(19) United States
(12) Patent Application Publication
(10) Pub. No.: US 2015/0001588 A1
(43) Pub. Date: Jan. 1, 2015

(54) SEMICONDUCTOR DEVICE AND METHOD FOR MANUFACTURING SAME

(71) Applicants: TOKYO ELECTRON LIMITED, Tokyo (JP); THE UNIVERSITY OF TOKYO, Tokyo (JP)

(72) Inventors: Isao Gunji, Tsukuba-shi (JP); Yusaku Kashiwagi, Tsukuba-shi (JP); Masakazu Sugiyama, Tokyo (JP)

(73) Assignee: Tokyo Electron Limited, Tokyo (JP)

(21) Appl. No.: 14/378,237

(22) PCT Filed: Feb. 5, 2013
(86) PCT No.: PCT/JP2013/052560

§ 371 Date: Aug. 12, 2014

(30) Foreign Application Priority Data
Feb. 13, 2012 (JP) 2012-028087

(51) Int. Cl. H01L 21/02; H01L 21/324

(52) U.S. Cl. CPC H01L 21/02587; H01L 21/02496; H01L 21/02381; H01L 21/02667; H01L 21/324; H01L 21/02433; H01L 21/02543
USPC 257/200; 438/492

(57) ABSTRACT

A trench 107 is coated and sealed with a cap film 111 from above an amorphous or polycrystalline InP film 109A buried in the trench 107. Next, a monocrystalline InP film 109B is formed by monocrystallizing the InP film 109A, with a Si (001) plane of the bottom of the trench 107 as a seed crystal plane, by melting InP by heating a Si wafer W at or above a melting point of InP and then solidifying InP by cooling InP.

### TECHNICAL FIELD

The present invention relates to a semiconductor device using semiconductor material other than silicon, and a method for manufacturing the same.

### BACKGROUND

Si wafers have been widely used as substrates in manufacturing super-LSIs for many years, and many manufacturing process device groups handling 12-inch large diameter substrates have been introduced into semiconductor device production factories around the world. Ge, InP, GaAs, InGaAs and the like known as semiconductors other than Si (hereinafter called also “heterogeneous semiconductors” in comparison with Si) may have higher carrier mobility and less band gap energy than Si. It is therefore expected that these heterogeneous semiconductors can be used as channel materials for the transistor to manufacture semiconductor devices having material properties superior to Si material properties. For example, if a fine structure of a high quality heterogeneous semiconductor can be formed on a Si wafer, it is possible to manufacture a super-LSI surpassing Si material properties using technologies and equipment developed so far. Therefore, it is considered that the performance of the super-LSI can be improved while avoiding production costs to be increased.

However, when films of these heterogeneous semiconductors are formed on the Si wafer, many lattice defects can occur in the heterogeneous semiconductor films due to a difference in lattice constant between Si and the heterogeneous semiconductor, which results in difficulty in achieving performance as expected.

There have been proposed Aspect Ratio Trapping (ART) methods, using a depth of an opening such as a trench or the like, in which lattice defects of a heterogeneous semiconductor film formed in an opening on monocrystalline Si are trapped near the bottom of the opening (see, e.g., Non-Patent Document 1 and Patent Documents 1 to 3). In these methods, an insulating film formed on a Si (100) plane is patterned in a predetermined shape and then, a heterogeneous semiconductor film is selectively grown in a bottom-up fashion from the Si (100) plane by means of a CVD method or the like. Since the lattice defects occurring near a boundary between the Si (100) plane and the heterogeneous semiconductor film are trapped by a side wall of the opening and confined in the lower part of the heterogeneous semiconductor film, no lattice defects will occur in the upper part of the heterogeneous semiconductor film. The methods disclosed in Non-Patent Document 1 and Patent Documents 1 to 3 can be applied only to an opening having a certain large aspect ratio (ratio of depth to opening width; depth/opening width) in order to confine the lattice defects. In addition, although the upper part of the heterogeneous semiconductor film has less lattice defects, it is difficult to reduce the lattice defects in the upper part of the heterogeneous semiconductor film to be practically used.

In addition, there has been also proposed another ART method in which an active area formed by Shallow Trench Isolation (STI) is dug down to a trench shape by dry etching and an InP film is selectively grown on a Si (001) plane of the bottom of the trench via a Ge buffer layer by means of a metal organic chemical vapor deposition (MOCVD) method (see, e.g., Non-Patent Document 2). This method may prevent lattice defects by interposing a layer of Ge having an intermediate lattice length, as a buffer layer, between Si and InP in order to alleviate lattice mismatch between Si and InP. However, this method also produces too many lattice defects in the upper part of the InP film to be practically used.

In addition, there have been also proposed so-called Rapid Melting Growth (RMG) methods used for growing a heterogeneous semiconductor film (see, e.g., Non-Patent Documents 3 and 4 and Patent Document 4). In these methods, an insulating film formed on a Si (100) plane is first patterned in a predetermined shape to expose a seed crystal plane. Thereafter, a heterogeneous semiconductor film such as Ge, GaAs or the like is formed by a sputtering method or a molecular beam epitaxy method. Next, the heterogeneous semiconductor film is etched in a stripe shape, is coated with an insulating film from above, and then is subjected to Rapid Thermal Annealing (RTA). The melted heterogeneous semiconductor material is liquid phase-epitaxially grown starting from a Si (100) seed crystal plane, thereby forming an elongated heterogeneous semiconductor film. At this time, by changing the growth direction of the heterogeneous semiconductor film from a direction perpendicular to the Si (100) plane to a direction parallel to the Si (100) plane in midway, lattice defects can be confined in near the Si (100) plane serving as a growth starting point. In the methods disclosed in Non-Patent Documents 3 and 4 and Patent Document 4, it is necessary to form the heterogeneous semiconductor film once on a large area and then etch it into a strip shape. This may result in low use efficiency of the heterogeneous semiconductor material and hence requires an additional photolithographic process or heterogeneous semiconductor fine etching process which may be challenging. In addition, a Si seed crystal plane in a semiconductor chip area obstructs the reduction of the chip area, which may result in very poor productivity.

### PRIOR ART DOCUMENTS

### Patent Documents

Patent Document 1: U.S. Pat. No. 7,626,246
Patent Document 2: U.S. Pat. No. 7,777,250
Patent Document 3: U.S. Pat. No. 7,799,592
Patent Document 4: U.S. Pat. No. 7,498,243

### Non-Patent Documents

Non-Patent Document 1: Applied Physics Letters, Vol. 90, 052113(2007)
Non-Patent Document 2: Journal of The Electrochemical Society, 157(11) H1023-H1028(2010)
Non-Patent Document 3: Applied Physics Letters, Vol.84, No.14, 5 April 2004
Non-Patent Document 4: IEEE. ELECTRON DEVICE LETTERS, VOL. 31, No.6, June 2010

### SUMMARY

The present invention provides some embodiments of a method for forming a micro structure of a lattice defect-free and high quality heterogeneous semiconductor material on a Si substrate.

According to one embodiment of the present invention, there is provided a method for manufacturing a semiconductor device, including: a first process of preparing a workpiece including a monocrystalline silicon layer, an insulating film formed on the monocrystalline silicon layer, and an opening formed in the insulating film to a depth at which a surface of the monocrystalline silicon layer is exposed; a second process of selectively burying a film made of heterogeneous semiconductor material, which is a different type of semiconductor material from silicon, in the opening of the insulating film; a third process of sealing the opening by coating the opening with a cap insulating film, the heterogeneous semiconductor material film being buried in the opening; a fourth process of forming a heterogeneous semiconductor material layer by monocrystallizing the heterogeneous semiconductor material, with the surface of the monocrystalline silicon layer as a seed crystal plane, by melting the heterogeneous semiconductor material film by heating the workpiece at a temperature of a melting point of the heterogeneous semiconductor material or higher and a melting point of the monocrystalline silicon or lower and then solidifying the heterogeneous semiconductor material film by cooling the heterogeneous semiconductor material film; and a fifth process of exposing at least a portion of a surface of the heterogeneous semiconductor material layer.

The heterogeneous semiconductor material may be one or more selected from a group consisting of Ge, InP, GaAs, InAs, AlSb, GaSb and InSb.

The opening may be a trench formed in the insulating film.

The opening may be a hole formed in the insulating film.

The first process may include: forming an insulating film on the monocrystalline silicon layer; forming the opening by etching the insulating film in a predetermined pattern; and uncovering a crystal orientation of an exposed surface of the monocrystalline silicon layer by cleaning the bottom of the opening. The surface crystal orientation of the monocrystalline silicon layer may be a (001) plane.

The first process may include: forming an insulating film on the monocrystalline silicon layer; etching the insulating film in a predetermined pattern; wet etching the monocrystalline layer to form the opening having an exposed a silicon (111) plane; and uncovering a crystal orientation of an exposed surface of the monocrystalline silicon layer exposed by cleaning the opening.

The second process may include: burying the heterogeneous semiconductor material film by a CVD method while heating the workpiece to a temperature ranging from 400 degrees Celsius or higher to 450 degrees Celsius or lower.

The fourth process may include heating the workpiece at a temperature rising rate of 50 degrees Celsius or higher.

The fourth process may include cooling the workpiece at a temperature falling rate of 50 degrees Celsius or higher.

The third process may include forming the cap insulating film in a plurality of layers.

In the third process, the cap insulating film may include a first cap layer of a SiO₂ film making direct contact with InP, and a second cap layer of a SiN film formed on the first cap layer.

In the third process, the cap insulating film may include a first cap layer of a SiN film making direct contact with InP, and a second cap layer of a SiO₂ film formed on the first cap layer.

In the third process, the cap insulating film may include a first cap layer of a SiN film making direct contact with InP, a second cap layer of a SiO₂ film formed on the first cap layer, and a third cap layer of a SiN film formed on the second cap layer.

The second process may be performed in a batch type MOCVD apparatus.

The workpiece may be s a monocrystalline substrate or a SOI substrate.

According to another embodiment of the present invention, there is provided a method for manufacturing a semiconductor device, including: preparing a workpiece including a monocrystalline silicon layer, an insulating film formed on the monocrystalline silicon layer, and an opening formed in the insulating film to a depth at which a surface of the monocrystalline silicon layer is exposed and selectively burying a film made of heterogeneous semiconductor material, which is a different type of semiconductor material from silicon, in the opening of the insulating film; and forming a heterogeneous semiconductor material layer by monocrystallizing the heterogeneous semiconductor material, with the surface of the monocrystalline silicon layer as a seed crystal plane, by melting the heterogeneous semiconductor material film by heating the workpiece at a temperature of a melting point of the heterogeneous semiconductor material or higher and a melting point of the monocrystalline silicon or lower and then solidifying the heterogeneous semiconductor material film by cooling the heterogeneous semiconductor material film.

According to another embodiment of the present invention, there is provided a semiconductor device manufactured by one of the above-described methods.

According to the semiconductor device manufacturing method of the present invention, by performing a heat-treatment to a heterogeneous semiconductor material selectively buried in an opening of an insulating film, it is possible to monocrystallize the heterogeneous semiconductor material with a surface of monocrystalline silicon exposed to the opening as a seed crystal plane. At this time, crystallinity of the heterogeneous semiconductor material layer can be improved by defect confining action using an aspect ratio of the opening and recrystallization by heat-treatment. Accordingly, with the method of the present invention, it is possible to form a micro structure of the heterogeneous semiconductor material having less defect and high quality crystallinity on the monocrystalline silicon layer in a simple process.

In addition, with the semiconductor device manufacturing method of the present invention, since there is no need to etch a formed heterogeneous semiconductor material layer, the heterogeneous semiconductor material layer can maintain the good crystallinity without being damaged. A semiconductor device having the micro structure of the heterogeneous semiconductor material obtained thus is suitable to be used for channels of fin type field effect transistors (FINFETs) and the like, quantum dot devices, photonic devices and so on.

### BRIEF DESCRIPTION OF THE DRAWINGS

FIGS. 1A to 1E are views for explaining one example of processes of a method for manufacturing a semiconductor device according to a first embodiment of the present invention.

FIGS. 2A to 2C are views for explaining one example of processes subsequent to FIGS. 1A to 1E.

FIGS. 3A to 3D are views for explaining one example of processes subsequent to FIGS. 2A to 2C.

FIG. 4 is a view showing melting points of various types of semiconductor materials.

FIG. 5 is a view for explaining a state where threading dislocation defects due to lattice mismatch are confined in the lower part of an InP film.

FIG. 6 is a view for explaining an example configuration of an InGaAs/InAlAs quantum well channel using a fin-structured InP film.

FIG. 7 is a view for explaining an example configuration of a planar InGaAs/InAlAs quantum well channel.

FIG. 8 is a view for explaining an example configuration of a stacked InGaAs/InAlAs quantum well channel using an InP film.

FIG. 9 is a view showing an example configuration of a stacked cap film.

FIG. 10 is a view showing another example configuration of the stacked cap film.

FIG. 11 is a view showing another example configuration of the stacked cap film.

FIG. 12 is a view for explaining a structure of a cap film of Test Example 1.

FIG. 13 is a scanning electron microscope (SEM) image showing a surface state of a cap film after annealing for Test Example 1.

FIG. 14 is a view for explaining a structure of a cap film of Test Example 2.

FIG. 15 is a SEM image showing a surface state of a cap film after annealing for Test Example 2.

FIG. 16 is a SEM image of a top surface of an InP film buried in a trench for Test Example 3.

FIG. 17 is a SEM image of a top surface of an InP film buried in a trench for Test Example 4.

FIG. 18 is a SEM image of a top surface of an InP film buried in a trench for Test Example 5.

FIG. 19 is a view showing comparison of InP film buried in trench between Test Example 3 and Test Example 5.

FIG. 20 is an optical microscope image of an InP film buried in a trench before annealing for Test Example 5.

FIG. 21 is an optical microscope image of an InP film buried in a trench after annealing for Test Example 5.

FIG. 22 is a schematic view for explaining a state of grains before the annealing corresponding to FIG. 20.

FIG. 23 is a schematic view for explaining a state of grains after the annealing corresponding to FIG. 21.

FIG. 24 is a transmission electron microscope (TEM) image of an InP film buried in a trench before annealing for Test Example 3.

FIG. 25 is a TEM image of an InP film buried in a trench after annealing for Test Example 3.

FIG. 26 is a view for explaining an example configuration of quantum dots.

FIGS. 27A to 27C are views for explaining one example of processes of a method for manufacturing a semiconductor device according to a third embodiment of the present invention.

FIGS. 28A to 2C are views for explaining one example of processes subsequent to FIGS. 27A to 27C.

FIGS. 29A to 29C are views for explaining one example of processes subsequent to FIGS. 28A to 28C.

### DETAILED DESCRIPTION

Embodiments of the present invention will now be described in detail with reference to the accompanying drawings.

### First Embodiment

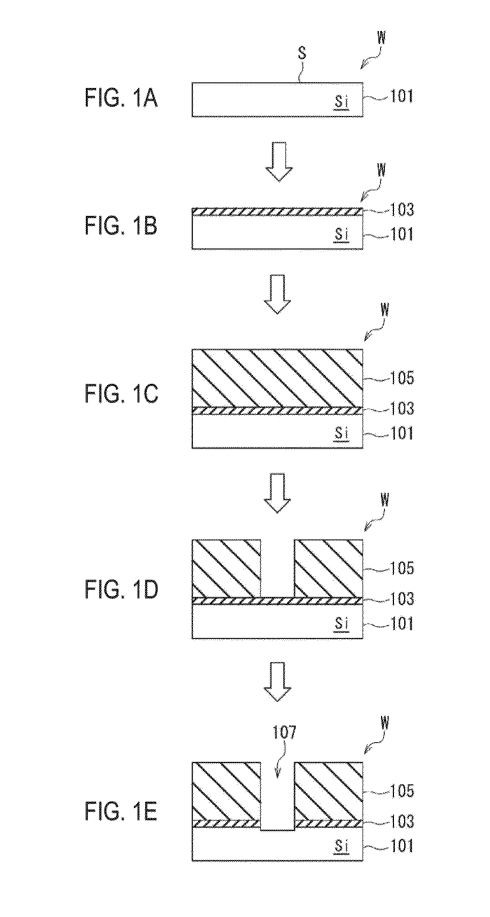

First, a method of manufacturing a semiconductor device according to a first embodiment of the present invention will be described with reference to FIGS. 1A to 3D. In this embodiment, a case where a Si wafer having a (001) plane is used as a workpiece having a monocrystalline silicon layer and InP is used as a heterogeneous semiconductor material to form a channel of a fin type field effect transistor (FINFET) will be described by way of example. FIGS. 1A to 3D are sectional views showing a surface of a Si wafer and the vicinity thereof, which is used to explain main processes of the semiconductor device manufacturing method according to this embodiment.

### (First Process)

A first process is a process of preparing a Si wafer W, as a workpiece, including an insulating film formed on a monocrystalline silicon 101, and a trench 107, as an opening (concave portion), formed in the insulating film to a depth at which a surface of the monocrystalline silicon 101 is exposed, as shown in FIG. 1E. First, as shown in FIG. 1A, the Si wafer W is prepared. In this embodiment, the Si wafer W corresponds to a monocrystalline silicon layer. A crystal orientation of the surface S of the monocrystalline silicon 101 of the Si wafer W corresponds to a (001) plane. Next, as shown in FIG. 1B, a SiN film (Si₃N₄ in stoichiometry, abbreviated as SiN) 103 is formed on the monocrystalline silicon 101 of the Si wafer W. A method for forming the SiN film 103 is not particularly limited but may include, for example, any deposition methods such as, for example, a thermal CVD method, a plasma CVD method, an ALD method, a SOD (Spin On Disk or Spin On Dielectric) method and the like.

Next, as shown in FIG. 1C, a SiO₂ film 105 is formed on the SiN film 103. A method for forming the SiO₂ film 105 is not particularly limited but may include, for example, any deposition methods such as, for example, a thermal CVD method, a plasma CVD method, an ALD method, a SOD method and the like.

Although two layers, i.e., the SiN film 103 and the SiO₂ film 105, are stacked as an insulating film forming therein an opening since a FINFET channel formation is the purpose of this embodiment, the insulating film may have either a single layer or three or more layers.

The thickness of the SiN film 103 may fall within a range of, for example, 5 nm to 20 nm for the purpose of forming the FINFET channel but is not limited thereto for other purposes. The thickness of the SiO₂ film 105 may fall within a range of, for example, 10 nm to 500 nm for the purpose of forming the FINFET channel but is not limited thereto for other purposes. In addition, in order to ensure a lattice defect confinement effect which will be described later, the thickness of the SiO₂ film 105 may be determined based on a ratio of a depth to an opening width of the trench 107 (depth/opening width, namely, aspect ratio).

Next, as shown in FIGS. 1D and 1E, the trench 107 is patterned by sequentially etching the SiO₂ film 105 and the SiN film 103 by means of photolithography. In this example, the etching is carried out until the (001) plane of the monocrystalline silicon 101 at the bottom of the trench 107 is exposed. That is, the etching is carried out until the depth of the trench 107 becomes equal to or more than the total thickness of the SiO₂ film 105 and the SiN film 103. The width of the trench 107 may be set as desired but may be preferably set based on the aspect ratio as described above.

The etching of the SiO₂ film 105 may be achieved, for example by performing a combination of the photolithography and the reactive ion etching (RIE) having high anisotropy after a resist layer (not shown) is formed. As conditions for the RIE, for example, a CFₓ or the like may be used as an etching gas. In addition, after the RIE, for example, an ashing process using oxygen plasma may be performed to remove residues of CF (fluorocarbon) compounds on the Si wafer W.

Subsequently, the etching of the SiN film 103 may be performed with the RIE, after etching the SiO₂ film 105. Alternatively, the etching of the SiN film 103 may be performed with wet etching using the SiO₂ film 105 as a mask. The wet etching may be performed, for example, using heated phosphoric acid (H₃PO₄) in order to obtain selectivity with the SiO₂ film 105.

After forming the trench 107 by the etching as shown in FIG. 1E, the crystal orientation may be uncovered clearly by cleaning the (001) plane of the monocrystalline silicon 101 exposed at the bottom of the trench 107. The cleaning may be performed, for example using a sulfuric acid hydrogen peroxide solution (SPM), hydrochloric acid hydrogen peroxide solution (SC2), dilute hydrofluoric acid (DHF) or the like. Removing a native oxide film on a seed crystal surface is also possible with dry etching using a gas mixture of HF and NH₃

### (Second Process)

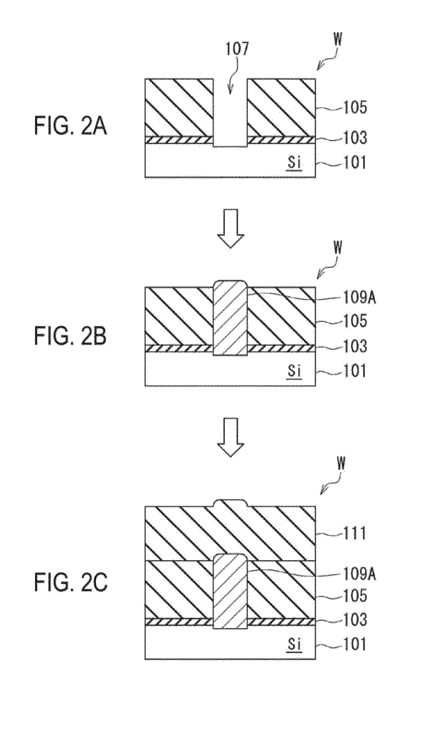

A second process is a process of selectively burying an amorphous or polycrystalline InP film 109A in the trench 107 of the Si wafer W. In this process, as shown in FIGS. 2A and 2B, the InP film 109A is selectively buried in a bottom-up way from the (001) plane of the monocrystalline silicon 101 at the bottom of the trench 107 using a Chemical Vapor Deposition (CVD) method or the like. This process is performed by a so-called Selective Area Growth (SAG) method using a difference in chemical state between the surface of the insulating film (SiO₂ film 105) and the Si (001) plane exposed at the bottom of the trench 107.

Examples of the CVD method used to bury the InP film 109A in the trench 107 may include a metal organic CVD (MOCVD) method, an atomic layer deposition (ALD) method and the like.

Here, the process of burying the InP film 109A in the trench 107 will be illustrated using the MOCVD as an example. In the MOCVD, the Si wafer W having the trench 107 is first placed in a processing chamber. Next, while heating the Si wafer W, the InP film 109A is formed by introducing a Group III compound material such as trimethylindium (TMIn), a Group V compound material such as tert-butylphosphine (TBP), and a H₂ gas or a N₂ gas as a carrier gas into the processing chamber. A film formation temperature (heating temperature of the Si wafer W) may fall within a range of, for example, 400 to 650 degrees Celsius, and, preferably 400 to 450 degrees Celsius for obtaining a small grain size of the InP film 109A in burying the InP material. For the InP material, if the film formation temperature in the MOCVD exceeds 450 degrees Celsius, grains of InP crystals filled in the trench 107 are significantly grown, which may cause the following problems (1) to (3): (1) unevenness of grains of crystals projecting toward the trench 107 is enlarged, which may cause difficulties when coating with a cap film 111; (2) the grains of crystals are hardly melted in a heating process of Rapid Melt Growth (RMG) because of their large size; and (3) even if the grains of crystals are melted, since the central portions of the grains of crystals are not likely to be melted and easy to remain as cores, grains are individually agglomerated and recrystallized, resulting in polycrystallization. On the other hand, if the film formation temperature in the MOCVD is less than 400 degrees Celsius, a film formation reaction itself is difficult to proceed, resulting in difficulty in burying the InP film 109A in the trench 107. On the other hand, if the film formation temperature for burying the InP material falls within a range of 400 to 450 degrees Celsius, since the grains are not excessively grown, the trench 107 can be compactly filled with the grains. Accordingly, without causing the above problems (1) to (3), an integrated monocrystalline InP film can be obtained after annealing.

In addition, during the film forming process, the internal pressure of the processing chamber may remain constant or be varied within a range of, for example, 10000 Pa to 100000 Pa.

### [Batch Type MOCVD Apparatus]

In the InP MOCVD burying process, a film formation rate is low when the film formation temperature is low, as described above. In a case where a 300 nm trench is filled, the MOCVD process time is about 60 minutes. Accordingly, for forming the film, it is preferable to use a batch type MOCVD apparatus capable of treating a plurality of wafers in a batch, rather than a single wafer MOCVD apparatus.

When the InP film 109A is buried in the trench 107, since the (001) plane of the monocrystalline silicon 101 is exposed at the bottom of the trench 107, the InP film 109A is selectively deposited in a bottom-up direction from the (001) plane of the monocrystalline silicon 101 in the trench 107 due to a difference in chemical state between the surface of the SiO₂ film 105 and the Si (001) plane. In this way, since a heterogeneous semiconductor material film can be formed only in a required portion (within the trench 107) by using the SAG method, a process of etching the heterogeneous semiconductor material film is not required.

Examples of the heterogeneous semiconductor material which is a different kind of semiconductor material from silicon may include Ge, GaAs, InAs, AlSb, GaSb, InSb and the like, which have a lower melting point than silicon, in addition to InP. Ge is a Group IV semiconductor and InP, GaAs, InAs, AlSb, GaSb and InSb are Group III-V semiconductors. In addition, a heterogeneous semiconductor material film buried in the trench 107 may be either amorphous or crystalline.

### (Third Process)

A third process is a process of sealing the trench 107 by coating the trench 107 with a cap film 111 as a cap insulating film on top of the InP film 109A buried in the trench 107. In this process, as shown in FIG. 2C, the cap film 111 is formed to cover the InP film 109A buried in the trench 107. This cap film 111 allows the InP film 109A to be sealed in the trench 107. That is, the InP film 109A in the trench 107 is surrounded by the monocrystalline silicon 101 in the lower side, the lateral insulating films (the SiN film 103 and the SiO₂ film 105) and the upper cap film 111, as if it is sealed in a small heating vessel.

The cap film 111 may be formed, for example by a low temperature CVD method at 200 degrees Celsius or so. An example of the low temperature CVD method may include a plasma CVD method. One example of the plasma CVD process used to form a SiO₂ film as the cap film 111 will be described below. First, the Si wafer W is placed in the processing chamber and is heated to a range of 100 to 300 degrees Celsius or so. The internal pressure of the processing chamber may fall within a range of, for example, 67 Pa to 400 Pa or so. Next, the cap film 111 can be formed above the trench 107 to seal the trench 107, by causing a decomposition reaction and an oxidation reaction by plasma, while supplying, for example, tetraethoxysilane (TEOS) as a raw material gas in a bubbling method into the processing chamber and separately supplying an oxidizing gas such as O₂ into the processing chamber. A SOD method may be also used to form the cap film 111. For example, the cap film 111 may be formed by coating a polysilazane solution using spin coating and then baking the same. The polysilazane solution forms a good quality silica film in a relatively low temperature process.

The thickness of the cap film 111 may fall within a range of, for example, 0.3 μm to 3 μm to ensure that the trench 107 is sealed and the cap film 111 has a sufficient heat storage function in a later heat treatment process.

Examples of the cap film 111 may include a SiN film, a SiON film, an Al₂O₃ film and the like, in addition to the SiO₂ film. In addition, in order to reduce reactivity of the cap film 111 with the top of the InP film 109A, the cap film 111 may include a layer which makes direct contact with InP of the heterogeneous material and is made of a heat resistant material (for example, SiN) which does not include oxygen. Accordingly, the cap film 111 may have a stacked structure including, for example, a first cap layer of a SiN film containing no oxygen and a second cap layer of a SiO₂ film or alternatively, may have a stacked structure including three or more layers to prevent crack of the cap film 111.

### (Fourth Process)

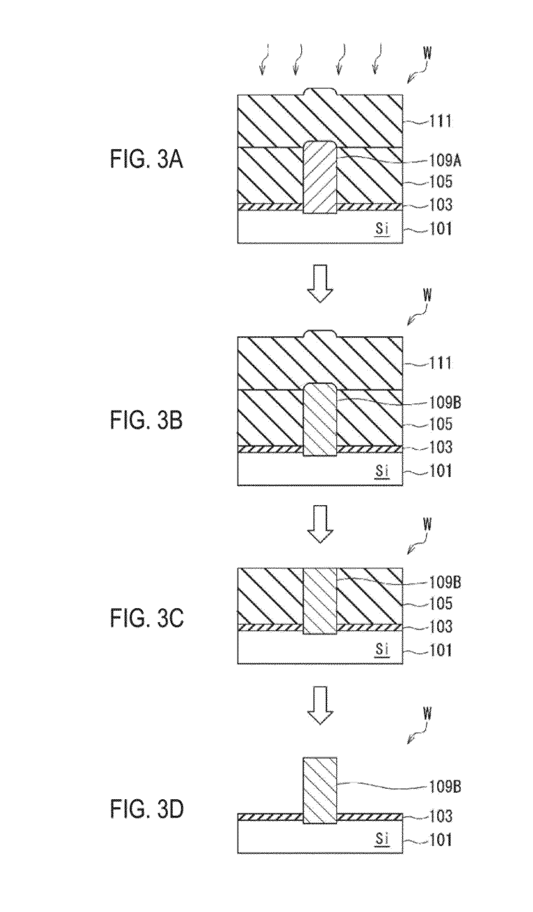

A fourth process is a process of forming a monocrystalline InP film 109B by monocrystallizing the InP film 109A, with the Si (001) plane at the bottom of the trench 107 as a seed crystal plane. The monocrystallizing is obtained by heating the Si wafer W at a temperature of InP melting point or higher and the monocrystalline silicon melting point or lower in order to melt the InP and then solidifying the InP by cooling the InP. In this process, InP monocrystals are grown using the liquid phase epitaxial growth by performing heat-treatment to the InP film 109A sealed by the trench 107 and the cap film 111. The heat-treatment may be performed by a Rapid Thermal Process (RTP) including rapid heating to a temperature of InP melting point or higher and rapid cooling thereafter. Alternatively, like the millisecond annealing, laser heating may be used to increase/decrease the temperature more rapidly. FIG. 3A shows a state where the Si wafer W is being heated and FIG. 3B shows a state after the Si wafer W is cooled. The heat-treatment allows the amorphous or polycrystalline InP film 109A in the trench 107 to be changed to the monocrystalline InP film 109B.

Heating in the heat-treatment process may be performed at a temperature rising rate of, for example, 50 degrees Celsius/sec or higher, to ensure that only InP is quickly melted while limiting a thermal budget and a throughput is improved. Cooling after the heating may be performed at a temperature falling rate of, for example, 50 degrees Celsius/sec or higher, in order to efficiently progress the liquid phase epitaxial growth of the monocrystalline InP from the molten state, starting from the Si (001) plane.

The monocrystallization by such heat-treatment is called a Rapid Melt Growth (RMG). The monocrystal growth by the RMG may provide a less-lattice defective and higher quality monocrystalline InP film 109B as compared to when the InP film is only formed on the Si (001) plane.

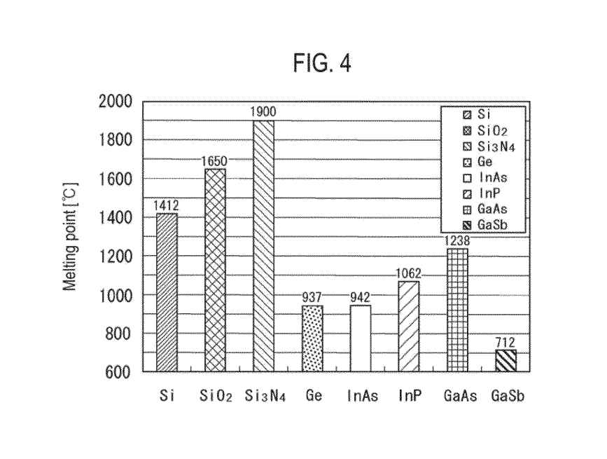

FIG. 4 is a graph showing melting points of Ge, InAs, InP, GaAs, and GaSb which are representative heterogeneous semiconductor materials, along with monocrystalline silicon, SiO₂ and SiN. Numbers shown on the graph denote melting points. The melting points of the bulk crystalline Si, SiO₂ and SiN are higher by at least 170 degrees Celsius than that of GaAs having the highest melting point among the exemplified heterogeneous semiconductor materials. In the RMG method, only a heterogeneous semiconductor material sealed in the insulating films (the SiO₂ film 105 and the SiN film 103) is melted because of such difference in melting points. Therefore, it is understood that the heating temperature in the heat-treatment may be a temperature ranging from the heterogeneous semiconductor material melting point or higher to the monocrystalline silicon melting point and lower.

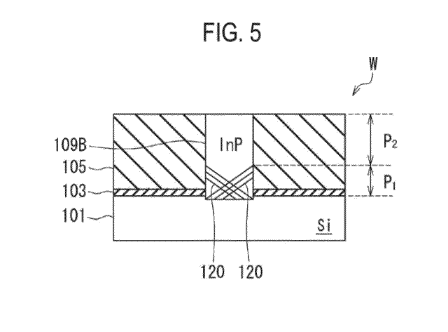

More specifically, for example, in a case of InP, only InP is melted by rapidly heating the InP to 1100 degrees Celsius at a temperature rising rate of 50 degrees Celsius/sec or higher and sustaining this temperature for 3 seconds. Thereafter, the molten InP may be recrystallized by rapidly cooling it at a temperature falling rate of 50 degrees Celsius/sec or higher. In the recrystallization, the Si (001) plane is used as a seed crystal. Although InP has a different crystal lattice from Si, the recrystallized InP takes over the crystallinity of the Si (001) plane. In this case, as shown in FIG. 5, threading dislocation defects 120 due to lattice mismatch occur in the monocrystalline InP film 109B. However, the threading dislocation defect 120 starting from an interface between the Si (001) plane and InP (001) plane in the monocrystalline InP film 109B has a directivity. Thus, the threading dislocation defect 120 is terminated at a boundary with a side wall of the trench 107. In other words, the threading dislocation defect 120 occurs only in the lower part P₁ of the monocrystalline InP 109B. Accordingly, by setting the aspect ratio (ratio of depth to opening width; depth/width) of the trench 107 to a certain level or higher, the upper part P₂ of the monocrystalline InP film 109B may have defect-free and high quality InP crystals.

Defect confinement using the aspect ratio in this way is an application of a so-called Aspect Ratio Trapping (ART) method. However, in typical ART methods, since only forming a heterogeneous semiconductor material film inside the trench 107 by SAG is performed, the quality of the heterogeneous semiconductor material film (the upper part P₂ of the monocrystalline InP film 109B) in the upper part of the trench 107 depends on a film forming method. On the contrary, the method according to this embodiment employs a combination of the SAG/ART and the RMG by heat-treatment, thereby making it possible to further improve the quality of the heterogeneous semiconductor material film (the upper part P₂ of the monocrystalline InP film 109B) in the upper part of the trench 107 through the recrystallization.

### (Fifth Process)

A fifth process is a process of exposing at least a portion of the surface of the monocrystalline InP film 109B by removing the cap film 111. In this process, the cap film 111 is first cut out by a Chemical Mechanical Polishing (CMP) process and then, when InP is exposed, successively, with the CMP process conditions changed, the top of the monocrystalline InP film 109B is flattened as shown in FIG. 3C. Under this state, in this embodiment, the SiO₂ film 105 is further removed by wet etching, thereby forming a fin structure of the monocrystalline InP film 109B, as shown in FIG. 3D. The wet etching of the SiO₂ film 105 may be performed, for example by using buffered hydrofluoric acid or the like.

In the manner described above, with the trench 107 formed in the SiN film 103 and SiO₂ film 105 as a mold, it is possible to form a fin-structured monocrystalline InP film 109B which can be used as a channel of a 3D transistor such as FINFET or the like.

In the exemplary processes shown in FIGS. 1A to 3D described above, detailed conditions on deposition, etching, cleaning and so on are not shown but all of which may be implemented by conventional methods.

In the method according to this embodiment, since the fin structure of the monocrystalline InP film 109B is defined by the trench 107 as a mold, patterning the InP film by means of the RIE or the like, as in the conventional fin-structured InP forming methods, is not necessary. Accordingly, when the monocrystalline InP film 109B is used as a FINFET channel, no plasma damage occurs in the channel. In addition, in the monocrystalline InP film 109B, the threading dislocation defects 120 due to the lattice mismatch are confined in the lower part P₁ near the interface between InP and Si and the upper part P₂ is formed as high quality InP monocrystals by the liquid phase epitaxial growth.

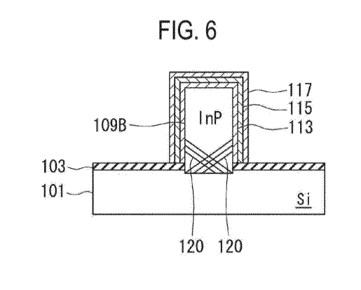

The fin-structured monocrystalline InP film 109B may be used to form a channel having, for example, a quantum well structure. The quantum well structure is a structure in which a layer having a very small band gap and low potential is interposed between layers having a large band gap and high potential. InP is known to be lattice-matched with InGaAs or InAlAs by adjusting an In:Ga ratio or an In:Al ratio. Therefore, the monocrystalline InP film 109B obtained by the method according to this embodiment may be used as a base layer for forming an InGaAs/InAlAs quantum well channel. FIG. 6 shows a case where the fin-structured monocrystalline InP film 109B of this embodiment is used to form an InGaAs/InAlAs quantum well channel. In FIG. 6, reference numerals 113, 115 and 117 denote an InAlAs layer as a lower barrier, an InGaAs as a channel layer, and an InP layer as an upper barrier, respectively.

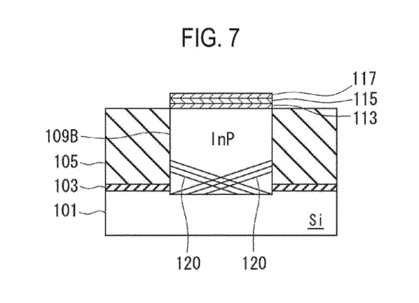

In addition, the semiconductor device manufacturing method according to this embodiment can be used to form a planar channel, in addition to the fin-structured channel. FIG. 7 shows a planar channel structure having an InGaAs/InAlAs quantum well channel. In this case, without removing the SiO₂ film 105 under the state shown in FIG. 3C, an InAlAs layer 113 as a lower barrier, an InGaAs layer 115 as a channel, and an InP layer 117 as an upper barrier may be formed and patterned on the monocrystalline InP film 109B.

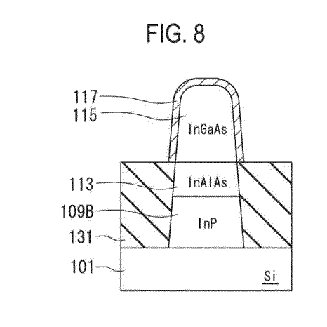

FIG. 8 shows another example configuration of the channel having the quantum well structure using the monocrystalline InP film 109B. FIG. 8 shows a case where a stacked InGaAs/InAlAs quantum well channel is formed using the monocrystalline InP film 109B. In FIG. 8, reference numerals 113, 115 and 117 denote an InAlAs layer as a lower barrier, an InGaAs as a channel layer, and an InP layer (or High-k layer) as an upper barrier, respectively. The monocrystalline InP film 109B and the InAlAs layer 113 are stacked and buried within a trench of a SiO₂ film 131 formed on the monocrystalline silicon 101.

In any example configurations of FIGS. 6, 7 and 8, InP is advantageous in that it has a good lattice constant that can be matched with that of InGaAs/InAlAs and accordingly eliminates a need to form a buffer layer such as GaAs or the like.

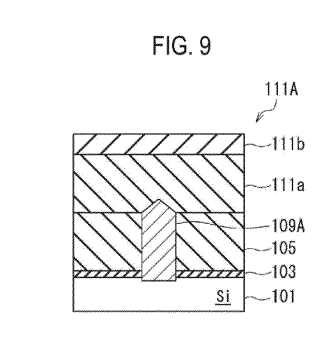

In addition, the semiconductor device manufacturing method according to this embodiment, the cap film 111 may be formed in a stacked structure, as described above. FIGS. 9 to 11 show example configurations of stack-structured cap films 111. A cap film 111A shown in FIG. 9 has a two-layered structure including a first cap layer 111a of a SOG—SiO₂ film making a direct contact with the InP film 109A and a second cap layer 111b of a SiN film stacked thereon. In this case, since the SOG—SiO₂ film is formed by a coating process, this film can coat the uneven top of the InP film 109A with high coverage performance. In addition, by forming a SiN film thereon, which has a coefficient of thermal expansion closer to Si than SiO₂, it is possible to prevent the cap film 111A from being cracked due to thermal strain applied to the SOG—SiO₂ film during the RMG process.

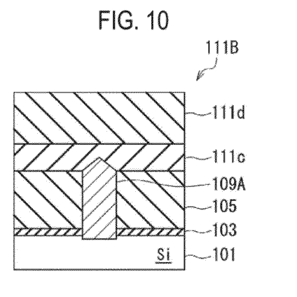

A cap film 111B shown in FIG. 10 has a two-layered structure including a first cap layer 111c of a SiN film making a direct contact with the InP film 109A and a second cap layer 111d of a SOG—SiO₂ film stacked thereon. In this case, by employing a SiN film having a coefficient of thermal expansion close to that of the Si of the base, as the first cap layer 111c, thermal strain during the RMG process can be alleviated. In addition, it is thought that stacking the SOG—SiO₂ film on the SiN film reinforces the CVD-SiN film having low coverage performance can be reinforced, thereby preventing the SiN film from being cracked at even a shallow portions during the RMG process.

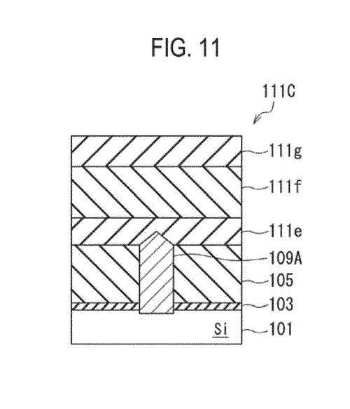

A cap film 111C shown in FIG. 11 has a three-layered structure including a first cap layer 111e of a SiN film making a direct contact with the InP film 109A, a second cap layer 111f of a SOG—SiO₂ film stacked thereon, and a third cap layer 111g of a SiN film stacked thereon. In this case, the SOG—SiO₂ film has a coefficient of thermal expansion significantly different from that of Si, and is sandwiched between the two-layers of SiN film each of which has a coefficient of thermal expansion close to that of Si. Thus, the thermal strain can be more alleviated during the RMG process. Further a vapor pressure of phosphorus (P) produced when InP is melted can be suppressed since the cap-stacked film can be made thicker.

### [Test Examples 1 and 2]

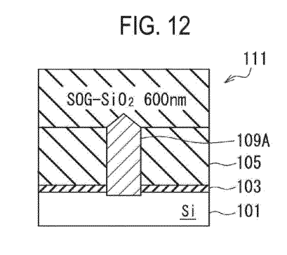

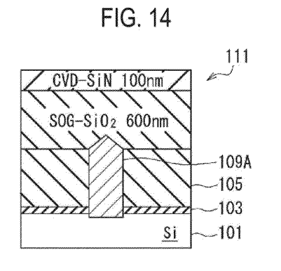

Next, test results of evaluation on a relationship between a structure and crack of a cap film 111 will be described with reference to FIGS. 12 to 15. In Test Example 1, as shown in FIG. 12, a 600 nm-thick SOG—SiO₂ film was formed as a cap film 111. In Test Example 2, as shown in FIG. 14, as a cap film 111, a 100 nm-thick plasma CVD-SiN film was stacked on a 600 nm-thick SOG—SiON₂ film. Then, each cap film 111 was subjected to annealing at 1100 degrees Celsius for 3 seconds by means of an RTP apparatus, with the InP film 109A sealed therein.

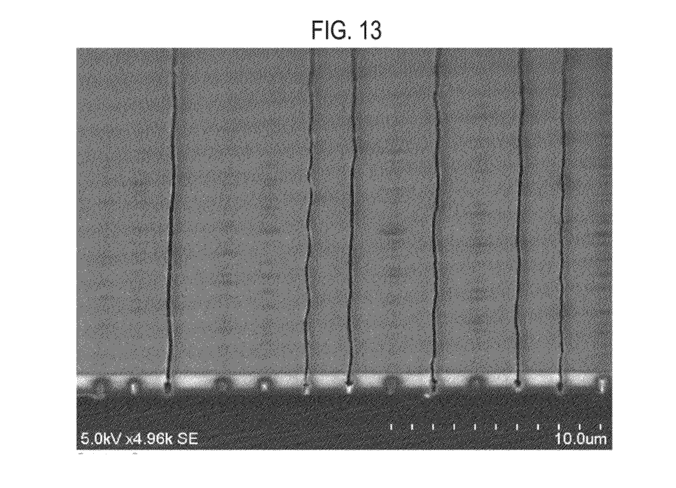

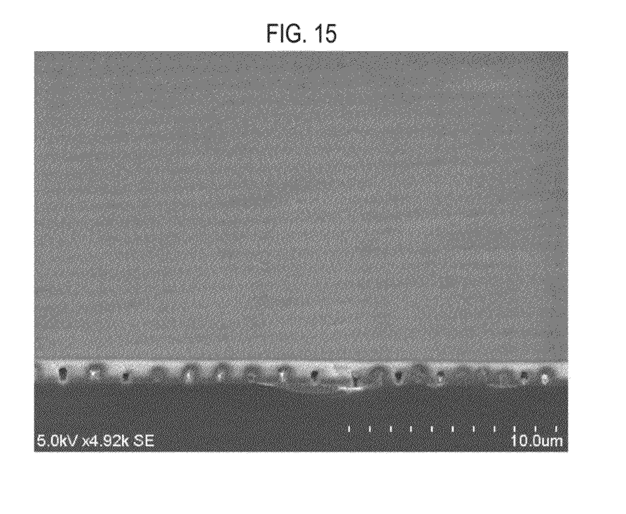

FIG. 13 is a SEM image showing a surface state after the annealing for Test Example 1. FIG. 15 is a SEM image showing a surface state after the annealing for Test Example 2. As can be seen from the comparison between FIG. 13 and FIG. 15, the cap film 111 of Test Example 1 of the single-layered SiO₂ film has cracks in the longitudinal direction of the trench 107 after the annealing but the cap film 111 of Text Example 2 of the SiO₂ film and the SiN film stacked thereon has no cracks. Therefore, it was confirmed by this experiment that, when the cap film 111 was formed in a two or more-layered structure including two different materials, the cap cracks during the annealing could be prevented.

### [Test Examples 3, 4 and 5]

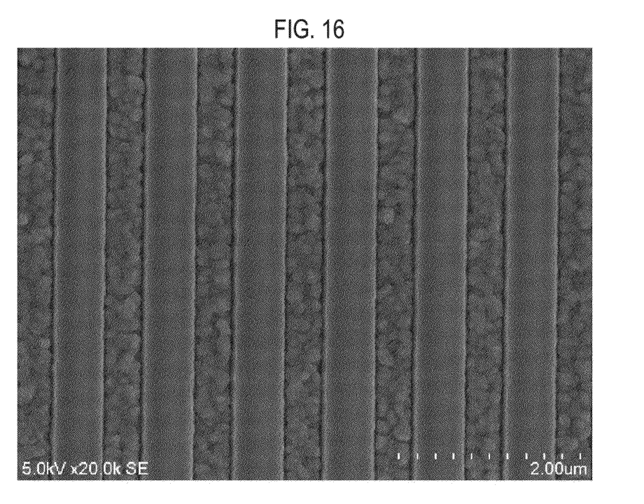

Next, test results of review on temperature conditions when the InP film 109A is formed by the MOCVD method in the second process will be described with reference to FIGS. 16 to 18. As described above, the second process is a process of selectively burying the amorphous or polycrystalline InP film 109A in the trench 107 of the Si wafer W. The MOCVD method was carried out by placing the Si wafer W having the trench 107 in the processing chamber, prebaking this wafer, performing a seed formation at 420 degrees Celsius, and then growing InP under different temperature conditions for 20 minutes. The temperature of the InP growth was set to 420 degrees Celsius for Test Example 3, 500 degrees Celsius for Test Example 4 and 550 degrees Celsius for Test Example 5. The internal pressure of the processing chamber was set to about 10,130 Pa (76 Torr). In the meantime, a partial pressure ratio of tert-butylphosphine (TBP) to trimethylindium (TMIn) was set to 60:1.

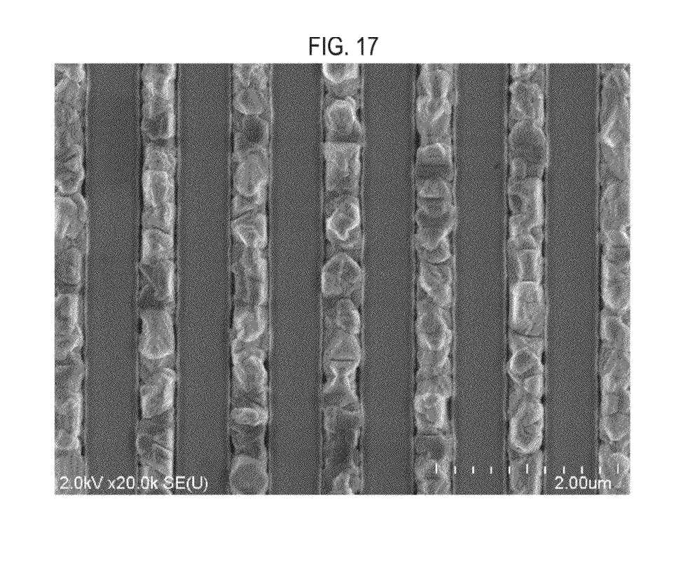

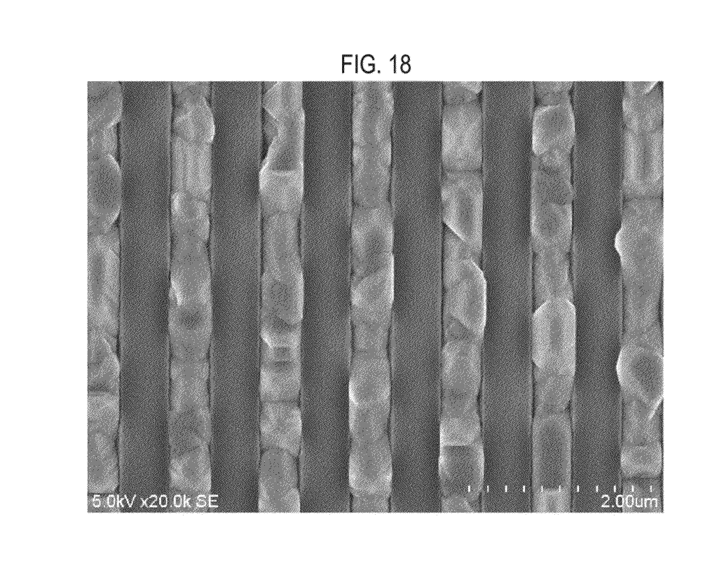

FIG. 16 is a SEM image of a top surface of the InP film 109A buried in the trench 107 for Test Example 3 (420 degrees Celsius). FIG. 17 is a SEM image of a top surface of the InP film 109A buried in the trench 107 for Test Example 4 (500 degrees Celsius). FIG. 18 is a SEM image of a top surface of the InP film 109A buried in the trench 107 for Test Example 5 (550 degrees Celsius). It can be seen from FIGS. 16 to 18 that, when comparing the InP film 109A in 420 degrees Celsius (Test Example 3), 500 degrees Celsius (Test Example 4) and 550 degrees Celsius (Test Example 5), grains G of the InP film 109A buried at 420 degrees Celsius have smaller crystals and higher compactness than grains G of the InP films 109A buried at 500 degrees Celsius and 550 degrees Celsius.

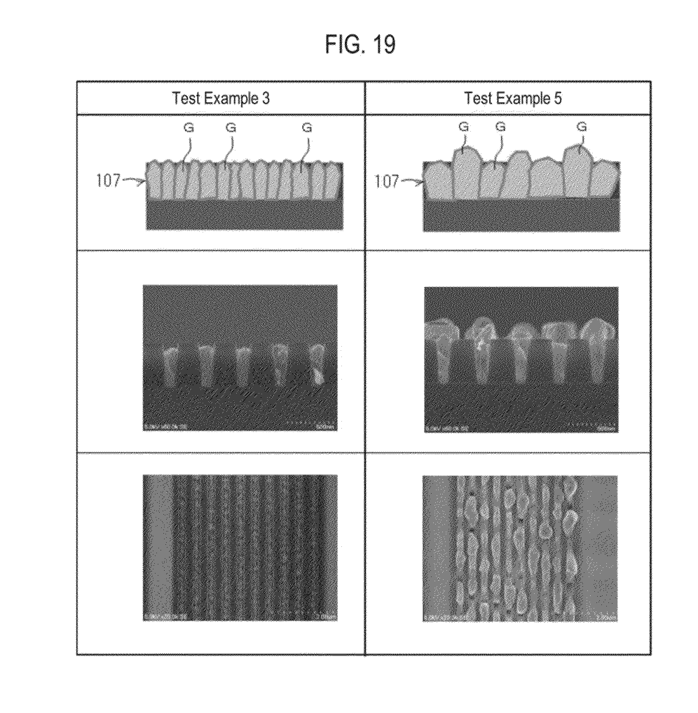

FIG. 19 shows comparison of more detailed state of the InP film 109A buried in the trench 107 between Test Example 3 (420 degrees Celsius) and Test Example 5 (550 degrees Celsius). The top of FIG. 19 schematically shows a shape of grains G of the InP film 109A buried in the trench 107. The middle of FIG. 19 is a SEM image of the longitudinal section of the InP film 109A buried in the trench 107 in the width direction of the trench 107 and the bottom of FIG. 19 is a SEM image of the top of the InP film 109A buried in the trench 107. As can be seen from FIG. 19, the unevenness of the top of the InP film 109A buried in the trench 107 is more restricted in 420 degrees Celsius (Test Example 3) than in 550 degrees Celsius (Test Example 5). In addition, the buried InP film 109A for 550 degrees Celsius (Test Example 5) has larger grains G and larger inter-grain G concave portions than that for 420 degrees Celsius (Test Example 3).

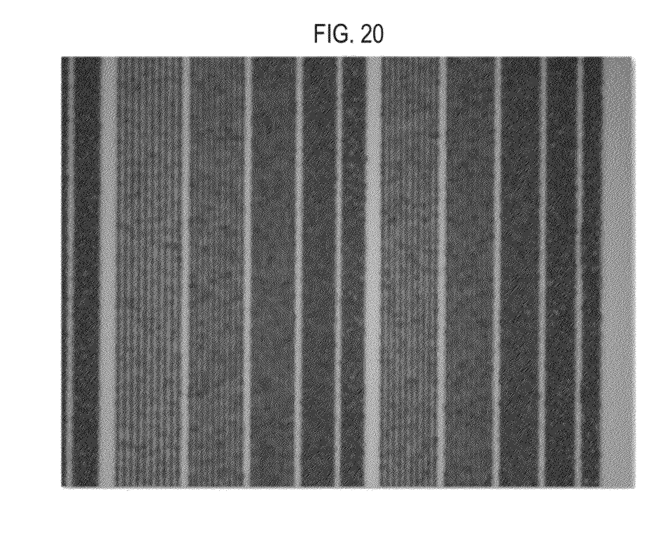

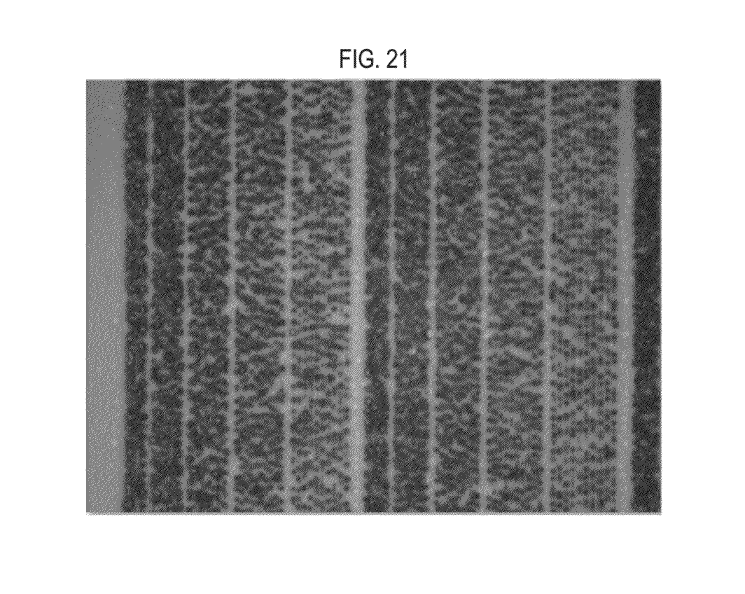

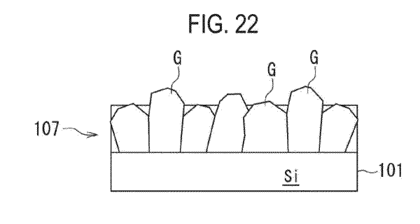

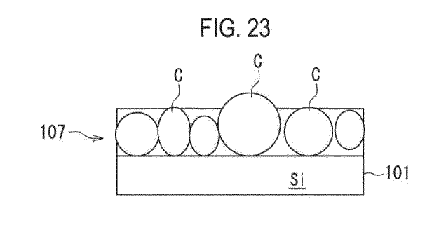

FIGS. 20 and 21 are optical microscope images of the InP film 109A buried in the trench 107 before and after annealing by a RMG (Rapid Melt Growth) method for Test Example 5 (550 degrees Celsius), respectively. FIG. 20 shows a state before annealing and FIG. 21 shows a state after annealing. FIGS. 20 and 21 also show a state where the cap film 111 is removed. FIG. 22 is a schematic view for explaining a state of grains G before the annealing (corresponding to FIG. 20) and FIG. 23 is a schematic view for explaining a state of grains G after the annealing (corresponding to FIG. 21). As shown in FIGS. 21 to 23, in Test Example 5 (550 degrees Celsius), since the grains G are large, even when annealing by the RMG method is performed, adjacent grains G may not be melted and combined together but may be individually separated from each other and agglomerated together in the trench 107, which results in alignment of spherical crystals C.

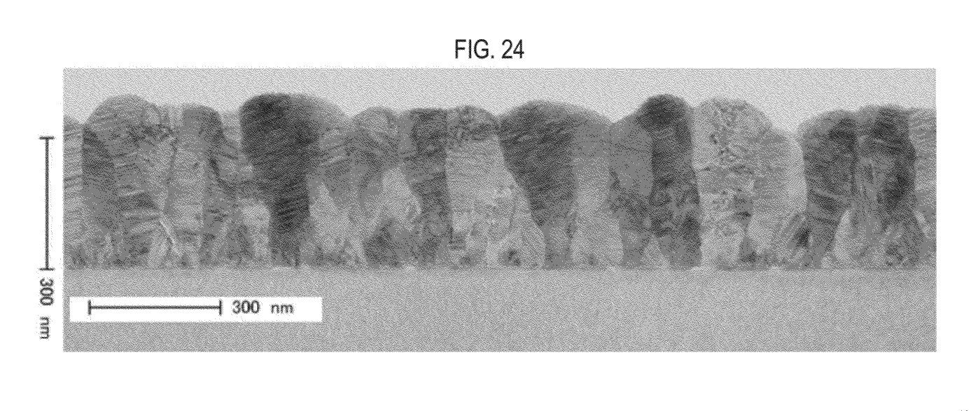

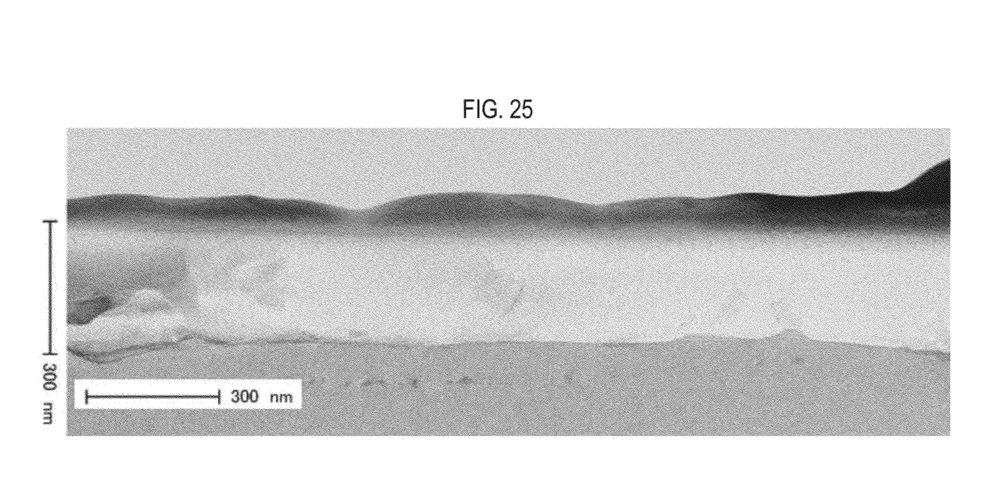

FIGS. 24 and 25 are TEM images of the InP film 109A buried in the trench 107 before annealing (FIG. 24) and after annealing (FIG. 25) by a RMG (Rapid Melt Growth) method in Test Example 3 (420 degrees Celsius), respectively. Both of FIGS. 24 and 25 show a longitudinal section of the trench 107. FIG. 24 (before annealing) shows a state where elongated InP crystal grains G are compactly buried in the trench 107. On the other hand, as opposed to FIGS. 21 and 23, FIG. 25 (after annealing) shows that individual grains G are melted into a single crystalline body to form the monocrystalline InP film 109B.

The results of Test Examples 3 to 5 have proved that, when a monocrystalline InP film 109B having less crystal defects is formed by combining the SAG (Selective Area Growth) method and the RMG (Rapid Melt Growth) method, the size of grains G of the InP film 109A buried in the trench 107 has an significant effect on a crystal shape after being melted. In order to form a high quality monocrystalline InP film 109B, it was effective to compactly bury grains G sufficiently smaller than the size (width and depth) of the trench 107 when the InP film 109A is buried in the trench 107. It was confirmed that this could be achieved when the film formation temperature in the MOCVD process is controlled to about 420 degrees Celsius, for example, fall within a range from 400 degrees Celsius to 450 degrees Celsius.

As described above, with the semiconductor device manufacturing method according to this embodiment, by annealing a heterogeneous semiconductor material sealed in an insulating film, it is possible to monocrystallize the heterogeneous semiconductor material with a surface of monocrystalline silicon 101 as a seed crystal plane. Accordingly, it is possible to form a micro structure of the heterogeneous semiconductor material having defect-free and high quality crystallinity, for example, the monocrystalline InP film 109B, on the Si wafer W in a simple process. In addition, with the semiconductor device manufacturing method according to this embodiment, since there is no need to etch a formed heterogeneous semiconductor material layer, the heterogeneous semiconductor material layer can maintain good crystallinity without being damaged.

### Second Embodiment

Although it has been illustrated in the first embodiment that the fin-structured channel is obtained by forming the trench 107 as an opening in the SiO₂ film 105 and SiN film 103 as insulating films, in a second embodiment, quantum dots by a heterogeneous semiconductor material is formed by forming holes as openings in an insulating film.

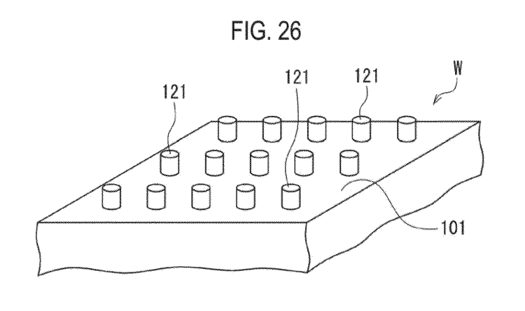

FIG. 26 is a perspective view showing one example configuration of quantum dots. As shown, quantum dots 121 made of a heterogeneous semiconductor material are formed in alignment on the monocrystalline silicon 101 of the Si wafer W.

The quantum dots 121 may be formed (not shown) by forming holes having a size corresponding to the quantum dots 121, as openings, instead of forming the trench 107 of the SiO₂ film 105, without providing the SiN film 103, for example, in the processes shown in FIGS. 1A to 3D. In the second embodiment, since the shape of the quantum dots 121 is defined with the holes formed in the SiO₂ film 105 as a mold, there is no need to use a self-organization effect by heating, as opposed to conventional quantum dot forming methods. Accordingly, it is possible to control the size, surface density and arrangement site of the quantum dots 121.

Such quantum dots 121 can be used, for example for single-electron transistors, quantum dot lasers and the like.

Other configurations and effects of the second embodiment are similar to those of the first embodiment and therefore, explanation of which will not be repeated for the purpose of brevity.

### Third Embodiment

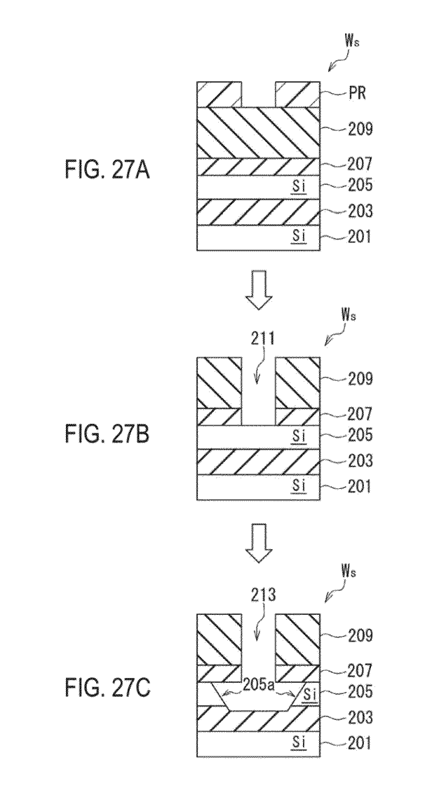

Next, a method of manufacturing a semiconductor device according to a third embodiment of the present invention will be described with reference to FIGS. 27A to 29C. Here, a Silicon On Insulator (SOI) wafer is used as a workpiece having a monocrystalline silicon layer. A case where a SOI wafer having a (001) plane is used as a workpiece and InP is used as a heterogeneous semiconductor material to form a channel of a fin type field effect transistor (FINFET) will now be described by way of example. FIGS. 27A to 29C are sectional views showing the vicinity of a surface of a SOI wafer, which is used to explain main processes of the semiconductor device manufacturing method according to this embodiment.

### (First Process)

A first process is a process of preparing a workpiece including a monocrystalline silicon layer, an insulating film formed thereon, and a trench as an opening (concave portion) formed in the insulating film. As shown in FIG. 27A, the SOI wafer Ws includes a silicon substrate 201, a SiO₂ film 203 (150 nm in thickness) as a BOX layer, and a Si layer 205 as a monocrystalline silicon layer. The Si layer 205 is a 50 nm-thick thin film formed with, for example, a P type semiconductor and has resistance of 9 to 18 Ω·cm. A surface crystal orientation of the Si layer 205 corresponds to the (001) plane. A SiN film 207 and a SiO₂ film 209 as insulating films are formed on the Si layer 205 of the SOI wafer WS.

A method for forming the SiN film 207 is not particularly limited but may include, for example, any deposition methods such as, for example, a thermal CVD method, a plasma CVD method, an ALD method, a SOD (Spin On Disk or Spin On Dielectric) method and the like.

A method for forming the SiO₂ film 209 is not particularly limited but may include, for example, any deposition methods using tetraethoxysilane (TEOS) as a raw material, such as, for example, a thermal CVD method, a plasma CVD method, an ALD method, a SOD method and the like.

Although, in this embodiment, two layers, i.e., the SiN film 207 and the SiO₂ film 209, are stacked as an insulating film formed therein with an opening for the purpose of forming the FINFET channel, the insulating film may have either a single layer or three or more layers.

The thickness of the SiN film 207 may fall within a range of, for example, 5 nm to 20 nm for the purpose of forming the FINFET channel but is not limited thereto for other purposes. The thickness of the SiO₂ film 209 may fall within a range of, for example, 10 nm to 500 nm for the purpose of forming the FINFET channel but is not limited thereto for other purposes. In addition, in order to ensure a lattice defect confinement effect which will be described later, the thickness of the SiO₂ film 209 may be determined based on a ratio of a depth to an opening width of a trench 213 (depth/opening width, namely, aspect ratio).

As shown in FIGS. 27A and 27B, a trench 211 having a predetermined pattern is formed by sequentially etching the SiO₂ film 209 and the SiN film 207, using a patterned resist layer PR as a mask, by means of photolithography. In this example, the etching is carried out until the (001) plane of the Si layer 205 is exposed at the bottom of the trench 211. That is, the etching is carried out until the depth of the trench 211 becomes equal to or more than the total thickness of the SiO₂ film 209 and the SiN film 207. The width of the trench 211 may be set as desired but may be preferably set based on the aspect ratio as described above.

The etching of the SiO₂ film 209 may be achieved by performing a combination of photolithography and the reactive ion etching (RIE) having high anisotropy. As conditions for the RIB, for example, a CFₓ or the like may be used as an etching gas. In addition, after the RIE, for example, an ashing process using oxygen plasma may be performed to remove residues of CF (fluorocarbon) compounds on the SOI wafer W.

Subsequently, the etching of the SiN film 207 may be performed with the RIE, after the etching of the SiO₂ film 209. Alternatively, the etching of the SiN film 207 may be performed with wet etching using the SiO₂ film 209 as a mask. The wet etching may be performed, for example using heated phosphoric acid (H₃PO₄) in order to obtain selectivity with the SiO₂ film 209.

Next, as shown in FIGS. 27B and 27C, using the SiN film 207 and SiO₂ film 209 as a mask, the Si layer 205 exposed at the bottom of the trench 211 is subjected to an anisotropic wet etching process using a mixture of a tetramethylammonium hydroxide (TMAH) aqueous solution or potassium hydroxide (KOH) aqueous solution and isopropyl alcohol. With this anisotropic wet etching, the lower portion of the trench 211 is etched to be widened in the horizontal direction (direction perpendicular to the stack direction of the film) to form a trench 213. Due to a difference in etching rate by the silicon surface orientation, the lower portion of the trench 213 has an inclined surface 205a inclined by an angle of 54.7° with respect to the surface of the Si layer 205 and a Si (111) plane is exposed on the inclined surface 205a. Here, assuming that an opening width of the trench 211 before the wet etching is L₀ and a depth of the trench 213 is D, a width L of the lower portion can be obtained by the following equation, L=L₀−2Dcot54.7. In this manner, in this embodiment, following the etching of the SiN film 207 and SiO₂ film 209, the Si layer 205 is wet-etched. Such multi-stage etching provides the following advantages. First, the Si (111) plane acts as a good seed crystal plane of InP since it has more binding species per unit area than the Si (100) plane and Si (110) plane and hence has high initial nucleation density and facilitates a dense crystal growth. In addition, by utilizing the Si (111) plane as a seed crystal plane, anti-phase grains due to a step structure of crystal surface is less likely to occur. In addition, as shown in FIG. 27C, by laterally etching the Si layer 205 to form the inverted “T”-like trench 213, trapping efficiency of defects in the lower portion of the trench 213 can be improved. Further, in the inverted “T”-like trench 213 as shown in FIG. 27C, if the Si layer 205 in the SOI wafer Ws is formed in advance to be thin, an area of a Si/InP interface can be reduced. For this reason, it is possible to reduce an effect of mixing of Si and InP in the RMG process. Therefore, a high quality monocrystalline InP film 215B can be formed in the subsequent process.

After forming the trench 213 by the etching, the crystal orientation may be clearly uncovered by cleaning the (111) plane of the Si layer 205 exposed on the inclined surface 205a of the lower portion of the trench 213. The cleaning may be performed, for example using a sulfuric acid hydrogen peroxide solution (SPM), hydrochloric acid hydrogen peroxide solution (SC2), dilute hydrofluoric acid (DHF) or the like. Removing a native oxide film on a seed crystal surface is also possible with dry etching using a gas mixture of HF and NH₃.

### (Second Process)

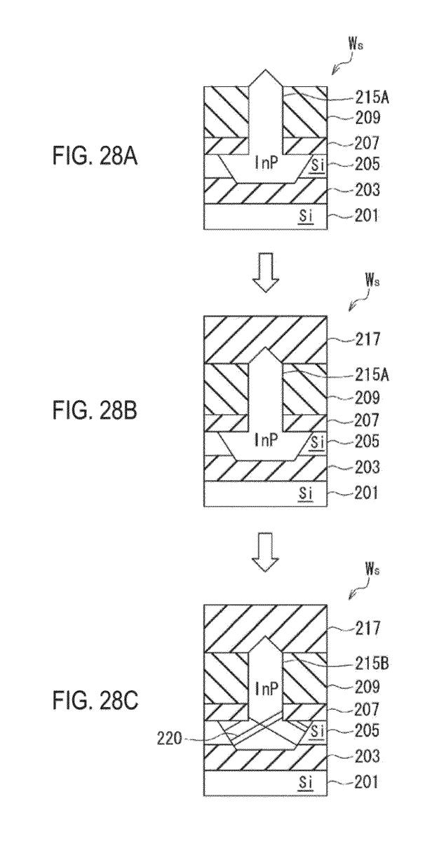

A second process is a process of selectively burying an amorphous or polycrystalline InP film 215A in the trench 213 of the SOI wafer WS. In this process, as shown in FIGS. 28A and 28B, the InP film 215A is selectively buried in a bottom-up direction from the extended lower portion of the trench 213 using a Chemical Vapor Deposition (CVD) method or the like. This process is performed by a so-called Selective Area Growth (SAG) method using a difference in chemical state between the surface of the insulating film (SiO₂ film 209) and the Si (111) plane of the Si layer 205 exposed in the trench 213.

Examples of the CVD method used to bury the InP film 215A in the trench 213 may include a metal organic CVD (MOCVD) method, an atomic layer deposition (ALD) method and the like.

Here, the process of burying the InP film 215A in the trench 213 will be illustrated with the MOCVD. In the MOCVD, the SOI wafer Ws having the trench 213 is placed in the processing chamber. Next, while heating the SOI wafer Ws to a range of, for example, 400 degrees Celsius to 650 degrees Celsius, preferably 400 degrees Celsius to 450 degrees Celsius, the InP film 215A is formed by introducing a Group III compound material such as trimethylindium (TMIn), a Group V compound material such as tert-butylphosphine (TBP), and a H₂ gas or a N₂ gas as a carrier gas into the processing chamber. During the film forming process, the total internal pressure of the processing chamber may remain constant or be varied within a range of, for example, 10000 Pa to 100000 Pa.

When the InP film 215A is buried in the trench 213, since the (111) plane is exposed to the inclined surface 205a of the Si layer 205, the InP film 215A is selectively deposited in a bottom-up direction from the (111) plane of the Si layer 205 in the trench 213 due to a difference in chemical state between the surface of the SiO₂ film 209 and the (111) plane. In this way, since a heterogeneous semiconductor material film can be formed only in a required portion (the trench 213) by using the SAG method, a process of etching the heterogeneous semiconductor material film is not required.

Examples of the heterogeneous semiconductor material which is a different kind of semiconductor material from silicon may include Ge, GaAs, InAs, AlSb, GaSb, InSb and the like, which have a lower melting point than silicon, in addition to InP. Ge is a Group IV semiconductor and InP, GaAs, InAs, AlSb, GaSb and InSb are Group III-V semiconductors. In addition, a heterogeneous semiconductor material film buried in the trench 213 may be either amorphous or crystalline.

### (Third Process)

A third process is a process of sealing the trench 211 by coating the trench 211 with a cap film 217 as a cap insulating film on top of the InP film 215A buried in the trench 213. In this process, as shown in FIG. 28B, the cap film 217 is formed to cover the InP film 215A buried in the trench 213. The InP film 215A is sealed in the trench 213 using the cap film 217. That is, the InP film 215A in the trench 213 is surrounded by the lower SiO₂ film 203, the lower lateral Si layer 205, the upper lateral insulating films (the SiN film 207 and the SiO₂ film 209) and the upper cap film 217, as if it is sealed in a small heating vessel.

The cap film 217 may be formed, for example by a low temperature CVD method at about 200 degrees Celsius. An example of the low temperature CVD method may include a plasma CVD method. One example of a plasma CVD process used to form a SiO₂ film as the cap film 217 will be described below. First, the SOI wafer Ws is placed in the processing chamber and is heated to a range of 100 degrees Celsius to 300° or so. The internal pressure of the processing chamber may fall within a range of, for example, 67 Pa to 400 Pa or so. Next, the cap film 217 can be formed on top of the trench 213 to seal the trench 213, by causing a decomposition reaction and ab oxidation reaction by plasma while supplying, e.g., tetraethoxysilane (TEOS) as a raw material gas in a bubbling method into the processing chamber and separately supplying an oxidizing gas such as O₂ into the processing chamber. A SOD method may be also used to form the cap film 217. For example, the cap film 217 may be formed by applying a polysilazane solution using spin coating and then baking the same. The polysilazane solution forms a good quality silica film in a relatively low temperature process.

The thickness of the cap film 217 may fall within a range of, for example, 0.3 μm to 3 μm to ensure that the trench 213 is sealed and the cap film 217 has a sufficient heat storage function in a later heat treatment process.

Examples of the cap film 217 may include a SiN film, a SiON film, an Al₂O₃ film and the like, in addition to the SiO₂ film. In addition, in order to reduce reactivity of the cap film 217 with the top of the InP film 215A, the cap film 217 may include a layer which makes a direct contact with InP of the heterogeneous material and is made of a heat resistant material (for example, SiN) which does not contain oxygen. Accordingly, although not shown, the cap film 217 may have a stacked structure including, for example, a first cap layer of a SiN film which contains no oxygen and a second cap layer of a SiO₂ film or alternatively may have a stacked structure including three or more layers to prevent crack of the cap film 217.

### (Fourth Process)

A fourth process is a process of forming a monocrystalline InP film 215B by monocrystallizing the InP film 215A, with the Si (111) plane of the inclined surface 205a of the Si layer 205 as a seed crystal plane. The monocrystallizing is obtained by heating the SOI wafer Ws at a temperature of the InP melting point or higher and the monocrystalline silicon melting point or lower and then solidifying the InP by cooling the InP. In this process, InP monocrystals are grown by the liquid phase epitaxial growth by performing heat-treatment to the InP film 215A sealed by the trench 213 and the cap film 217. The heat-treatment may be performed by a Rapid Thermal Process (RTP) including rapid heating to temperature of the InP melting point or higher and rapid cooling thereafter. Alternatively, like the millisecond annealing, laser heating may be used to increase/decrease the temperature more rapidly. FIG. 28C shows a state after the SOI wafer Ws is cooled. The heat-treatment allows the amorphous or polycrystalline InP film 215A in the trench 213 to be changed to the monocrystalline InP film 215B.

Heating in the heat-treatment process may be performed at a temperature rising rate of, for example, 50 degrees Celsius/sec or higher, to ensure that only InP is quickly melted while limiting a thermal budget and a throughput is improved. Cooling after the heating may be performed at a temperature falling rate of, for example, 50 degrees Celsius/sec or higher, in order to efficiently progress the liquid phase epitaxial growth of the monocrystalline InP from the molten state, starting from the Si (111) plane.

The monocrystallization by such heat-treatment is called a Rapid Melt Growth (RMG). Monocrystal growth by the RMG may provide a less-lattice defective and higher quality monocrystalline InP film 215B as compared to when the InP film is only formed on the Si (111) plane.

In the RMG method, only a heterogeneous semiconductor material sealed in the insulating films (the SiO₂ film 209 and the SiN film 207) is melted using different melting points. Therefore, it is understood that the heating temperature in the heat-treatment may be a temperature ranging from heterogeneous semiconductor material melting point or higher to monocrystalline silicon melting point or lower.

More specifically, for example, in a case of InP, only the InP is melted by rapidly heating the InP to 1100 degrees Celsius at a temperature rising rate of 50 degrees Celsius/sec or higher and sustaining this temperature for 3 seconds and, thereafter, the molten InP may be recrystallized by being rapidly cooled at a temperature falling rate of 50 degrees Celsius/sec or higher. In the recrystallization, the Si (111) plane of the inclined surface 205a of the Si layer 205 is used as a seed crystal. Although InP has a different crystal lattice from Si, the recrystallized InP takes over the crystallinity of the Si (111) plane. In this case, as shown in FIG. 28C, threading dislocation defects 220 due to lattice mismatch occur in the monocrystalline InP film 215B. However, since a threading dislocation defect 220 starting from an interface between the Si (111) plane and InP (111) plane in the monocrystalline InP film 215B has a directivity, the threading dislocation defect 220 is terminated at a boundary with a side wall of the trench 213. In other words, the threading dislocation defect 220 occurs only in the lower portion of the monocrystalline InP 215B. Accordingly, by setting the aspect ratio (ratio of depth to opening width; depth/width) of the trench 213 to a certain level or larger, the upper portion of the monocrystalline InP film 215B may have defect-free and high quality InP crystals. In addition, in this embodiment, since the inverted “T”-like trench 213 is formed by the above-described multi-stage etching process and InP is buried therein, lattice defects are highly likely to be concentrated on InP of the extended lower portion of the trench 213 in the Si layer 205, thereby providing the upper portion of the monocrystalline InP film 215B with good crystallinity.

In the typical ART method, since only forming a heterogeneous semiconductor material film inside the trench 213 by the SAG is performed, the quality of the heterogeneous semiconductor material film (the upper portion of the monocrystalline InP film 215B) in the upper portion of the trench 213 depends on a film forming method. On the contrary, the method according to this embodiment employs a combination of the SAG/ART and the RMG by heat-treatment, thereby making it possible to even more improve the quality of the heterogeneous semiconductor material film (the upper portion of the monocrystalline InP film 215B) in the upper portion of the trench 213 through the recrystallization.

### (Fifth Process)

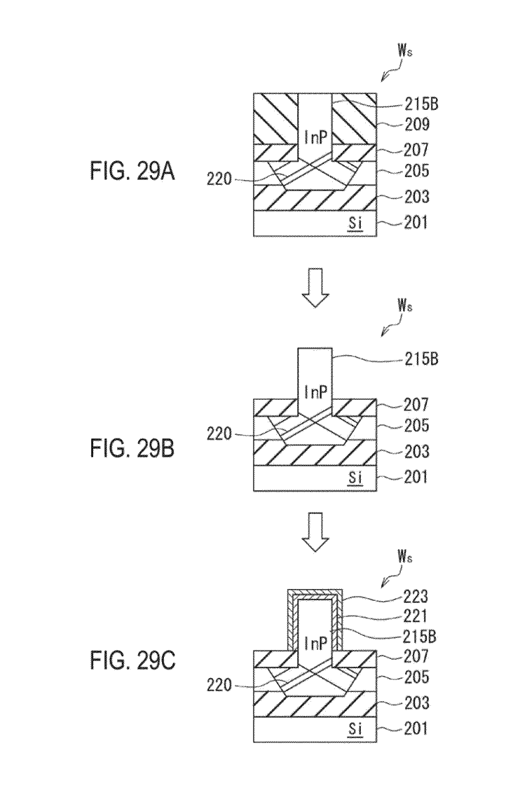

A fifth process is a process of exposing at least a portion of the surface of the monocrystalline InP film 215B by removing the cap film 217. In this process, the cap film 217 is first cut out by a Chemical Mechanical Polishing (CMP) and then, when InP is exposed, successively, with the CMP process conditions changed, the top of the monocrystalline InP film 215B is flattened as shown in FIG. 29A. Under this state, in this embodiment, the SiO₂ film 209 is further removed by wet etching, thereby forming a fin structure of the monocrystalline InP film 215B, as shown in FIG. 29B. The wet etching of the SiO₂ film 209 may be performed, for example, by using buffered hydrofluoric acid or the like.

In the manner described above, with the trench 213 formed in the Si layer 205, the SiN film 207 and the SiO₂ film 105 as a mold, it is possible to form a fin-structured monocrystalline InP film 215B which can be used as a channel of a 3D transistor such as FINFET or the like.

In the method according to this embodiment, since the fin structure of the monocrystalline InP film 215B is defined by the trench 213 as a mold, there is no need to pattern the InP film by means of the RIE or the like, unlike the conventional fin-structured InP forming methods. Accordingly, when the monocrystalline InP film 215B is used as a FINFET channel, no plasma damage occurs in the channel. In addition, in the monocrystalline InP film 215B, the threading dislocation defects 220 due to the lattice mismatch are confined in the lower portion near the interface between InP and Si and the upper portion is formed with high quality InP monocrystals by the liquid phase epitaxial growth.

The fin-structured monocrystalline InP film 215B may be used to form a channel having, for example, a quantum well structure. The quantum well structure is a structure in which a layer having a very small band gap and low potential is interposed between layers having a large band gap and high potential. It is known that InP is lattice-matched by adjusting an In:Ga ratio or an In:Al ratio with InGaAs or InAlAs. Therefore, the monocrystalline InP film 215B obtained by the method according to this embodiment may be used as a base layer for forming an InGaAs/InAlAs quantum well channel.

FIG. 29C shows a case where the fin-structured monocrystalline InP film 215B of this embodiment is used to form an InGaAs/InAlAs quantum well channel. In FIG. 29C, reference numerals 221 and 223 denote an InAlAs layer as a lower barrier and an InGaAs as a channel layer, respectively. In addition, although not shown, the semiconductor device manufacturing method according to this embodiment can be used to form a planar channel, in addition to the fin-structured channel. In any example configurations, InP is advantageous in that it has good lattice constant that can be matched with InGaAs/InAlAs and accordingly eliminates a need to form a buffer layer such as GaAs or the like.

In the exemplary processes shown in FIGS. 27A to 29C described above, detailed conditions on deposition, etching, cleaning and so on are not shown but all of which may be implemented by conventional methods.

As described above, with the semiconductor device manufacturing method according to this embodiment, by performing heat-treatment to a heterogeneous semiconductor material sealed in an insulating film, it is possible to monocrystallize the heterogeneous semiconductor material with the Si (111) plane as a seed crystal plane. Accordingly, it is possible to form a micro structure of the heterogeneous semiconductor material having less defect and high quality crystallinity, for example, the monocrystalline InP film 215B, on the SOI wafer Ws in a simple process. In addition, in the semiconductor device manufacturing method according to this embodiment, since there is no need to etch a formed heterogeneous semiconductor material layer, the heterogeneous semiconductor material layer can maintain good crystallinity without being damaged.

Other configurations and effects of this embodiment are similar to those of the first embodiment and therefore, explanation of which will not be repeated for the purpose of brevity. In addition, in the semiconductor device manufacturing method according to this embodiment, holes may be formed instead of the trenches 211 and 213 and the method may be, for example, applied to form the quantum dots described in the second embodiment.

Although the exemplary embodiments of the present invention have been described in detail for the purpose of illustration, the present invention is not limited to the disclosed embodiments. For example, although it has been illustrated in the above embodiments that the surface crystal orientation of the monocrystalline silicon 101 is a (001) plane or a (111) plane, the present invention is not limited thereto. For example, the monocrystalline silicon 101 may have other surface crystal orientations such as a (110) plane and the like.

In addition, although, in the above embodiments, the semiconductor device manufacturing methods of the present invention have been illustrated with transistor channel formation, the present invention is not limited thereto. For example, the semiconductor device manufacturing methods of the present invention may be applied for manufacture of photonic devices such as LEDs, semiconductor lasers, photodetectors, solar cells and so on.

This international application claims the benefit of Japanese Patent Application No. 2012-028087, filed on Feb. 13, 2012, in the Japan Patent Office, the disclosure of which is incorporated herein in its entirety by reference.

### EXPLANATION OF REFERENCE NUMERALS

101: monocrystalline silicon, 103: SiN film, 105: SiO₂ film, 107: trench, 109A: InP film, 109B: monocrystalline InP film, 111: cap film, W: Si wafer

What is claimed is:

1. A method for manufacturing a semiconductor device, comprising:
a first process of preparing a workpiece including a monocrystalline silicon layer, an insulating film formed on the monocrystalline silicon layer, and an opening formed in the insulating film to a depth at which a surface of the monocrystalline silicon layer is exposed;
a second process of selectively burying a film made of heterogeneous semiconductor material, which is a different type of semiconductor material from silicon, in the opening of the insulating film;
a third process of sealing the opening by coating a top of the opening with a cap insulating film, the heterogeneous semiconductor material film being buried in the opening;
a fourth process of forming a heterogeneous semiconductor material layer by monocrystallizing the heterogeneous semiconductor material, with the surface of the monocrystalline silicon layer as a seed crystal plane, by melting the heterogeneous semiconductor material film by heating the workpiece at a temperature of a melting point of the heterogeneous semiconductor material or higher and a melting point of the monocrystalline silicon or lower and then solidifying the heterogeneous semiconductor material film by cooling the heterogeneous semiconductor material film; and
a fifth process of exposing at least a portion of a surface of the heterogeneous semiconductor material layer.

2. The method of claim 1, wherein the heterogeneous semiconductor material is one or more selected from a group consisting of Ge, InP, GaAs, InAs, AlSb, GaSb and InSb.

3. The method of claim 1, wherein the opening is a trench formed in the insulating film.

4. The method of claim 1, wherein the opening is a hole formed in the insulating film.

5. The method of claim 1, wherein the first process includes:
forming an insulating film on the monocrystalline silicon layer;
forming the opening by etching the insulating film in a predetermined pattern; and
uncovering a crystal orientation of an exposed surface of the monocrystalline silicon layer by cleaning the bottom of the opening.

6. The method of claim 5, wherein the surface crystal orientation of the monocrystalline silicon layer is a (001) plane.

7. The method of claim 1, wherein the first process includes:
forming an insulating film on the monocrystalline silicon layer;
etching the insulating film in a predetermined pattern;
wet etching the monocrystalline silicon layer to form the opening having an exposed silicon (111) plane; and
uncovering a crystal orientation of an exposed surface of the monocrystalline silicon layer by cleaning the opening.

8. The method of claim 1, wherein the second process includes:
burying the heterogeneous semiconductor material film by a CVD method while heating the workpiece to a temperature ranging from 400 degrees Celsius or higher to 450 degrees Celsius or lower.

9. The method of claim 1, wherein the fourth process includes heating the workpiece at a temperature rising rate of 50 degrees Celsius or higher.

10. The method of claim 1, wherein the fourth process includes cooling the workpiece at a temperature falling rate of 50 degrees Celsius or higher.

11. The method of claim 1, wherein the third process includes forming the cap insulating film in a plurality of layers.

12. The method of claim 1, wherein, in the third process, the cap insulating film includes a first cap layer of a SiO₂ film making direct contact with InP, and a second cap layer of a SiN film formed on the first cap layer.

13. The method of claim 1, wherein, in the third process, the cap insulating film includes a first cap layer of a SiN film making a direct contact with InP, and a second cap layer of a SiO₂ film formed on the first cap layer.

14. The method of claim 1, wherein, in the third process, the cap insulating film includes a first cap layer of a SiN film making direct contact with InP, a second cap layer of a SiO₂ film formed on the first cap layer, and a third cap layer of a SiN film formed on the second cap layer.

15. The method of claim 1, wherein the second process is performed in a batch type MOCVD apparatus.

16. The method of claim 1, wherein the workpiece is a monocrystalline substrate or a SOI substrate.

17. A method for manufacturing a semiconductor device, comprising:
preparing a workpiece including a monocrystalline silicon layer, an insulating film formed on the monocrystalline silicon layer, and an opening formed in the insulating film to a depth at which a surface of the monocrystalline silicon layer is exposed and selectively burying a film made of heterogeneous semiconductor material, which is a different type of semiconductor material from silicon, in the opening of the insulating film; and
forming a heterogeneous semiconductor material layer by monocrystallizing the heterogeneous semiconductor material, with the surface of the monocrystalline silicon layer as a seed crystal plane, by melting the heterogeneous semiconductor material film by heating the workpiece at a temperature of a melting point of the heterogeneous semiconductor material or higher and a melting point of the monocrystalline silicon or lower and then solidifying the heterogeneous semiconductor material film by cooling the heterogeneous semiconductor material film.

18. A semiconductor device manufactured by the method of claim 1.
